(19) United States
(12) Patent Application Publication
(10) Pub. No.: US 2015/0206897 A1
(43) Pub. Date: Jul. 23, 2015

(54) SEMICONDUCTOR DEVICE AND MANUFACTURING METHOD THEREOF

(71) Applicant: KABUSHIKI KAISHA TOSHIBA, Minato-ku (JP)

(72) Inventor: Takuji KUNIYA, Yokkaichi-Shi (JP)

(73) Assignee: KABUSHIKI KAISHA TOSHIBA, Minato-ku (JP)

(21) Appl. No.: 14/325,747

(22) Filed: Jul. 8, 2014

(30) Foreign Application Priority Data
Jan. 21, 2014 (JP) 2014-008764

(51) Int. Cl. H01L 27/115; H01L 29/49; H01L 29/423; H01L 29/45

(52) U.S. Cl. CPC H01L 27/11582; H01L 27/11565; H01L 29/45; H01L 29/4916; H01L 29/42344

(57) ABSTRACT

A semiconductor device according to the embodiment includes a first stack structure. The first stack structure includes at least one first insulating film and a plurality of first conducting films above a surface of a substrate. A link portion electrically connects the first conducting films in the first stack structure. A second stack structure includes a plurality of second insulating films and a plurality of second conducting films on the first stack structure. A semiconductor pillar passes through the second stack structure to reach the first stack structure and is insulated from the first and second stack structures.

### CROSS REFERENCE TO RELATED APPLICATIONS

This application is based upon and claims the benefit of priority from the prior Japanese Patent Application No. 2014-008764, filed on Jan. 21, 2014, the entire contents of which are incorporated herein by reference.

### FIELD

The embodiments of the present invention relate to a semiconductor device and manufacturing method thereof.

### BACKGROUND

A three-dimensional memory using a three-dimensional cell stack technology has been developed to increase the capacity of a NAND flash memory (hereinafter, also simply “memory”) and to reduce the cost. The three-dimensional memory includes a stack structure in which control electrodes of memory cells and insulating films thereof are alternately stacked, and silicon pillars that pass through the stack structure. The silicon pillars are formed in trenches (hereinafter, also “memory holes”) passing through the stack structure and reaching a back gate (one of select gates).

In this type of three-dimensional memory, many control electrodes and many insulating films are stacked and thus aspect ratios of the memory holes are quite high. Normally, the back gate is formed of polysilicon and the memory holes need to be reached to the middle of polysilicon. A CF-based gas is frequently used to etch polysilicon.

However, because the CF-based gas contains carbon, CF-based depositions adversely attach to side surfaces (side surfaces of polysilicon) at bottom portions of the memory holes. In this case, the widths (diameters) of the bottom portions of the memory holes are reduced and it is difficult to form the memory holes as designed. Therefore, during formation of the memory holes, an overetching time is conventionally lengthened to increase the widths of the bottom portions of the memory holes to some extent. However, when the overetching time is lengthened, the side surfaces of the memory holes are likely to have tapered shapes. Furthermore, excess overetching or use of an etching gas other than CF-based one causes bowing on the side surfaces at upper portions of the memory holes. Besides, a mask material is greatly lost due to excess overetching or use of an etching gas other than CF-based one. Therefore, it is difficult to achieve ensuring of the widths of the bottom portions of the memory holes and maintaining of satisfactory shapes of the memory holes at the same time.

### BRIEF DESCRIPTION OF THE DRAWINGS

FIG. 1 is a cross-sectional view showing an example of a configuration of a three-dimensional NAND flash memory 100 according to an embodiment;

FIG. 2 is a schematic plan view showing an example of a configuration of the memory 100 shown in FIG. 1;

FIGS. 3A to 7C are cross-sectional views showing an example of a manufacturing method of the memory 100 according to the present embodiment;

FIG. 8A is a view showing a layout pattern of the sacrifice layer 95;

FIG. 8B is a view showing a layout of the sacrifice layer 95 and the BG link portions 50; and

FIG. 8C is a view showing a layout of the hollow HL, the memory holes MH, and the insulating films 60.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to the embodiment includes a first stack structure. The first stack structure includes at least one first insulating film and a plurality of first conducting films above a surface of a substrate. A link portion electrically connects the first conducting films in the first stack structure. A second stack structure includes a plurality of second insulating films and a plurality of second conducting films on the first stack structure. A semiconductor pillar passes through the second stack structure to reach the first stack structure and is insulated from the first and second stack structures.

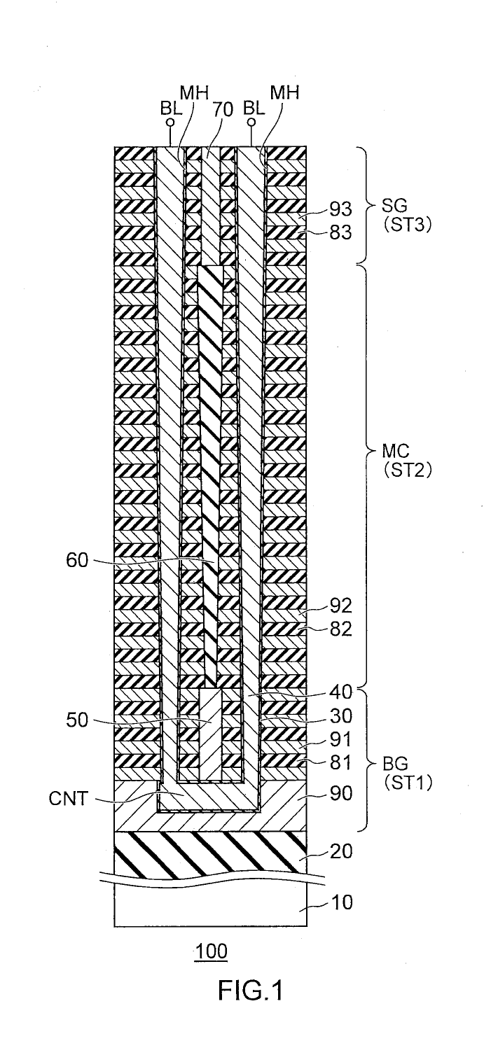

FIG. 1 is a cross-sectional view showing an example of a configuration of a three-dimensional NAND flash memory 100 (hereinafter, also simply “memory 100”) according to an embodiment. The memory 100 includes a substrate 10, an insulating film 20, a back gate portion BG, memory cells MC, a select gate portion SG, a charge accumulation layer 30, silicon pillars (body portions) 40, BG link portions 50, insulating films 60, and SG link portions 70.

The substrate 10 is a semiconductor substrate such as a silicon substrate. A peripheral circuit (not shown) that controls the back gate portion BG, the memory cells MC, and the select gate portion SG, and other parts are provided on a surface of the substrate 10. The insulating film 20 is an interlayer dielectric film that covers the peripheral circuit and is an insulating film such as a silicon dioxide film or a silicon nitride film.

The back gate portion BG serving as a first select portion includes a first stack structure ST1. The first stack structure ST1 is formed by alternately stacking a plurality of first insulating films 81 and a plurality of first conducting films 90 and 91. The first conducting films 90 and 91 are provided on the insulating film 20 and are formed of, for example, doped polysilicon or doped amorphous silicon containing boron. Each of the first insulating films 81 is provided between the first conducting film 90 and the first conducting film 91 or between the first conducting films 91 and is formed of an oxide film such as a silicon dioxide film. In the present embodiment, the plural first insulating films 81 and the plural first conducting films 91 are provided. However, only one first insulating film 81 can be provided. In this case, the first insulating film 81 is provided between the first conducting film 90 and the first conducting film 91.

Each of the BG link portions 50 is provided in the first stack structure ST1 between two of the silicon pillars 40 adjacent to each other and electrically connects the first conducting films 90 and 91. The BG link portions 50 extend in a stack direction of the first conducting films 90 and 91 and the first insulating films 81. The BG link portions 50 are formed of a conducting material such as polysilicon or tungsten containing carbon. On the other hand, the BG link portions 50 face a silicon-pillar coupling portion CNT with the charge accumulation layer 30 interposed therebetween and are insulated from the silicon-pillar coupling portion CNT. The first conducting films 90 and 91 in the first stack structure ST1 are electrically connected by each of the BG link portions 50, thereby functioning as a single gate electrode of the back gate portion BG.

The memory cells MC include a second stack structure ST2 provided on the back gate portion BG. The second stack structure ST2 is formed by alternately stacking a plurality of second insulating films 82 and a plurality of second conducting films 92. The second conducting films 92 are formed of, for example, doped polysilicon or a metal silicide containing boron. When the second conducting films 92 are formed of a metal silicide, the second conducting films 92 are lower in the resistance and can be easily found to be different from the first conducting films 91 (polysilicon, for example). Each of the second insulating films 82 is provided between layers of the second conducting films 92 and is formed of an insulating film such as a silicon dioxide film. Each layer of the second conducting films 92 is insulated by the second insulating films 82 and functions as a gate electrode of each of the memory cells MC.

The select gate portion SG serving as a second select portion includes a third stack structure ST3 provided on the memory cells MC. The third stack structure ST3 is formed by alternately stacking a plurality of third insulating films 83 and a plurality of third conducting films 93. The third conducting films 93 are formed of, for example, doped polysilicon or amorphous silicon containing boron. Each of the third insulating films 83 is provided between the third conducting films 93 and is formed of an insulating film such as a silicon dioxide film.

The SG link portions 70 are provided in the third stack structure ST3 and electrically connect the plurality of third conducting films 93. The SG link portions 70 extend in a stack direction of the third insulating films 83 and the third conducting films 93. The SG link portions 70 are formed of, for example, a conducting material such as polysilicon or tungsten containing carbon. The third conducting films 93 in the third stack structure ST3 are electrically connected to each other by each of the SG link portions 70 and can function as a gate electrode of the select gate portion SG.

In the present embodiment, the plural third insulating films 83 and the plural third conducting films 93 are provided. However, the third insulating films 83 and the third conducting films 93 can be formed of a single conducting material. In this case, the third insulating films 83 and the third conducting films 93 are formed of, for example, a conducting material such as doped polysilicon containing boron.

Memory holes MH are formed in the select gate portion SG, the memory cells MC, and the back gate portion BG. The memory holes MH pass through the third and second stack structures ST3 and ST2 and are formed to the middle of the conducting film 90 of the first stack structure ST1.

The charge accumulation layer 30 is formed to cover the inner surfaces of the memory holes MH. The charge accumulation layer 30 is, for example, an insulating film containing a silicon nitride film and is formed of a stack insulating film such as an ONO film or an NONON film. The ONO film is a stack film including a silicon dioxide film, a silicon nitride film, and a silicon dioxide film. The NONON film is a stack film including a silicon nitride film, a silicon dioxide film, a silicon nitride film, a silicon dioxide film, and a silicon nitride film. Of course, the charge accumulation layer 30 can be an insulating film having another configuration as long as it contains a material that can trap charges. The nitride film of the charge accumulation layer 30 has a function to accumulate therein charges (electrons, for example) from the silicon pillars (the body portion) 40. The nitride film of the charge accumulation layer 30 accumulates charges therein or emits charges therefrom, whereby the memory cells MC can store logic data therein.

The silicon pillars 40 are provided in the memory holes MH and are insulated from the first to third stack structures ST1 to ST3 by the charge accumulation layer 30. Two of the silicon pillars 40 adjacent to each other are electrically connected by the silicon-pillar coupling portion CNT provided in the first conducting film 90 at the bottom portions of the memory holes MH. The silicon-pillar coupling portion CNT and the silicon pillars 40 are formed simultaneously and are formed of a same material (doped silicon, for example). The silicon-pillar coupling portion CNT faces the first conducting film 90 and the BG link portions 50 with the charge accumulation layer 30 interposed therebetween and is insulated from the first conducting film 90 and the BG link portions 50.

Each of the insulating films 60 is provided in the second stack structure ST2 between two of the silicon pillars 40 adjacent to each other. The insulating films 60 are provided to pass through the second stack structure ST2 in a stack direction of the second insulating films 82 and the second conducting films 92. Accordingly, the second stack structure ST2 is separated to correspond to two of the silicon pillars 40 adjacent to each other, respectively. Parts of the second stack structure ST2 separated by each of the insulating films 60 are electrically insulated from each other and function as control electrodes of the memory cells MC different from each other, respectively. That is, the memory cells MC corresponding to two of the silicon pillars 40 adjacent to each other are separated by the insulating film 60.

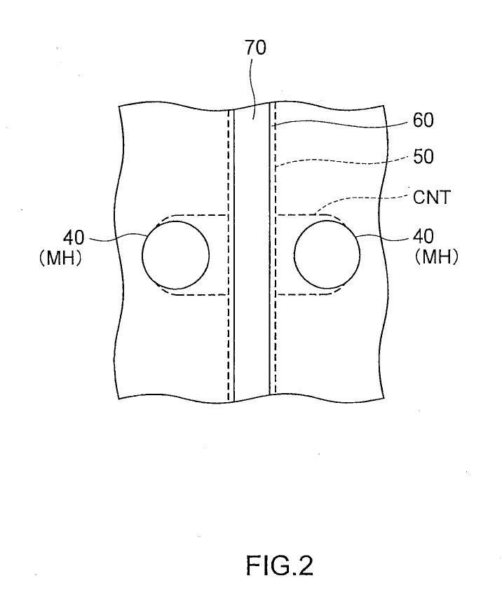

FIG. 2 is a schematic plan view showing an example of a configuration of the memory 100 shown in FIG. 1. Two of the silicon pillars 40 adjacent to each other are electrically connected by the silicon-pillar coupling portion CNT at the bottom portions of the memory holes MH. The BG link portion 50, the insulating film 60, and the SG link portion 70 are provided between two of the silicon pillars 40 adjacent to each other.

The silicon pillars 40 are connected to different bit lines BL, respectively. The conducting films 92 of the second stack structure ST2 function as different control electrodes (word lines), respectively. The memory 100 flows current in a group of memory cells MC (hereinafter, also “memory string”) selected by the select gate portion SG and the back gate portion BG. This enables a sense amplifier (not shown) to detect conduction states of the memory cells MC selected by the control electrodes via the corresponding bit lines BL. The sense amplifier or a write driver (not shown) can write data by accumulating charges in the charge accumulation layer 30 or erase data by emitting charges from the charge accumulation layer 30.

In the memory 100 according to the present embodiment, the gate electrodes of the back gate portion BG as well as the memory cells MC have the stack structure including the insulating films 81 and the conducting films 91.

If the gate electrodes of the back gate portion BG are formed of a single polysilicon layer, CF-based depositions (carbon-containing depositions) adversely attach to the side surfaces (side surfaces of polysilicon) at the bottom portions of the memory holes due to etching with a CF-based gas as mentioned above. In this case, the depositions serve as a mask and the widths (diameters) at the bottom portions of the memory holes are reduced, so that it is difficult to form the memory holes as designed.

In contrast, according to the present embodiment, the gate electrodes of the back gate portion BG have the stack structure including the insulating films 81 and the conducting films 91. The insulating films 81 are formed of an oxide film such as a silicon dioxide film. Accordingly, during formation of the memory holes MH, the insulating films 81 and the conducting films 91 are alternately etched also in the gate electrodes of the back gate portion BG (the bottom portions of the memory holes MH). Therefore, while CF-based depositions are produced during etching of the conducting films 91 (polysilicon, for example), oxygen is supplied during etching of the insulating films 81 (a silicon dioxide film, for example). The depositions produced during etching of the conducting films 91 are thus oxidized during etching of the insulating films 81 and are reduced or disappear.

When the depositions at the bottom portions of the memory holes MH are reduced or disappear, etching of the widths (diameters) at the bottom portions of the memory holes MH progresses and thus the memory holes MH close to a design value can be obtained. Because this eliminates the need of excess overetching, satisfactory shapes of the memory holes MH can be maintained and also adverse influences on the peripheral circuit can be suppressed. Furthermore, it is unnecessary to use an etching gas other than CF-based one. As a result, according to the present embodiment, it is easy to achieve ensuring of the widths at the bottom portions of the memory holes MH and maintaining of satisfactory shapes of the memory holes MH at the same time.

The first insulating films 81 are provided to supply oxygen during formation of the memory holes MH. Therefore, the first insulating films 81 suffice to be thick enough to supply oxygen and can be thinner than the second insulting films 82. When the first insulating films 81 conversely have a thickness equal to or larger than that of the second insulating films 82, the memory holes MH become deeper. That is, the aspect ratios of the memory holes MH become larger. Accordingly, it is preferable that the first insulating films 81 be as thin as possible so long as the first insulating films 81 can supply oxygen.

A manufacturing method of the memory 100 according to the present embodiment is explained next.

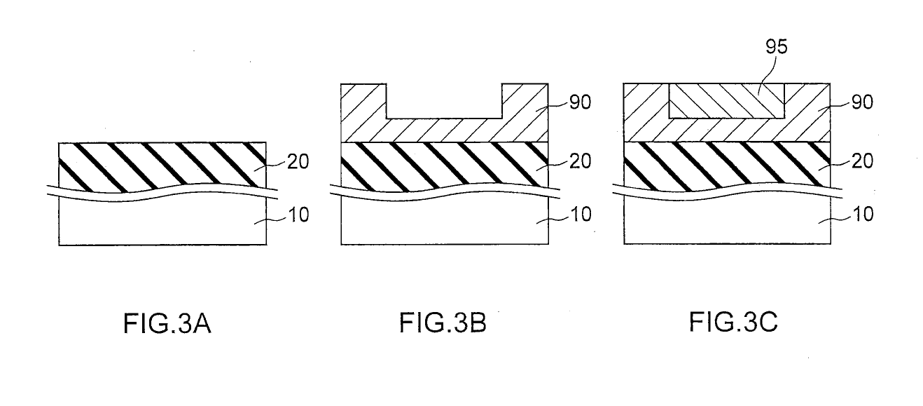

FIGS. 3A to 7C are cross-sectional views showing an example of a manufacturing method of the memory 100 according to the present embodiment. A peripheral circuit and the like (not shown) are first formed on the substrate 10. The insulating film 20 is then formed to cover the peripheral circuit as shown in FIG. 3A. The insulating film 20 can be, for example, a silicon dioxide film (a TEOS (Tetraethoxysilane) film) or a silicon nitride film.

A material of the first conducting film 90 is then deposited on the insulating film 20. The first conducting film 90 is then processed in a layout pattern of the silicon-pillar coupling portion CNT using a lithographic technique and an etching technique as shown in FIG. 3B. The first conducting film 90 can be, for example, doped polysilicon containing boron.

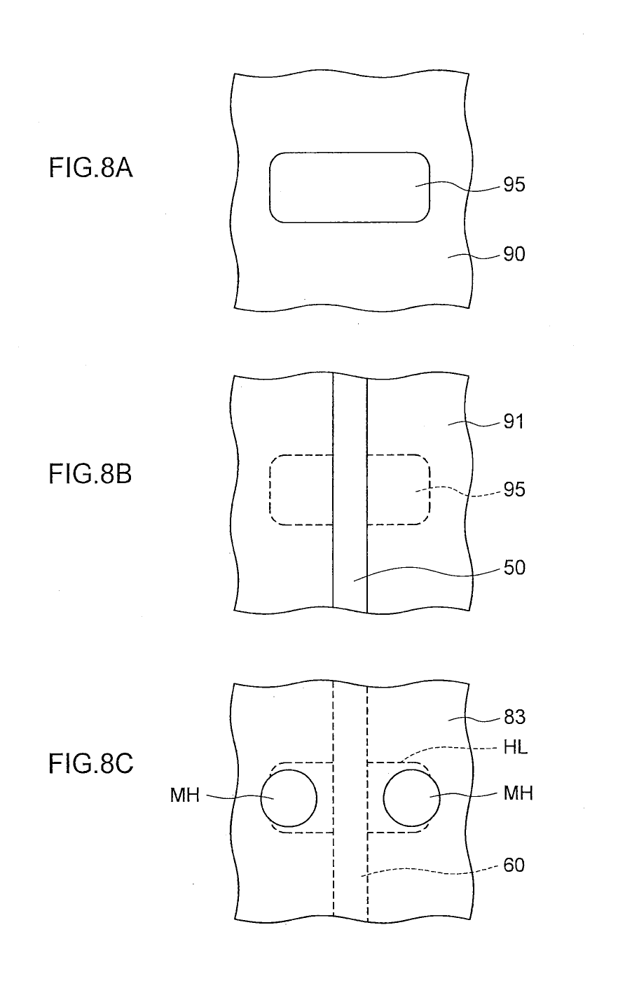

A sacrifice layer 95 is then deposited on a formation area of the silicon-pillar coupling portion CNT and then the sacrifice layer 95 is flattened by a CMP (Chemical Mechanical Polishing) method or the like. A structure shown in FIG. 3C is thereby obtained. The sacrifice layer 95 is formed of non-doped polysilicon, for example. FIG. 8A is a view showing a layout pattern of the sacrifice layer 95 (that is, a layout pattern of the silicon-pillar coupling portion CNT).

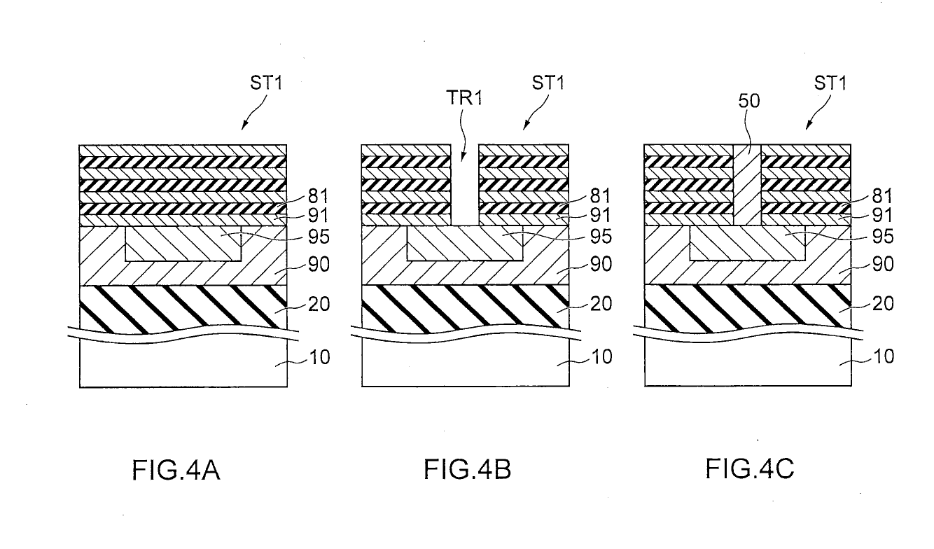

Desired numbers of the first insulating films 81 and the first conducting films 91 are then stacked as shown in FIG. 4A. Accordingly, the first stack structure ST1 is formed. The first insulating films 81 are formed of an oxide film such as a silicon dioxide film and the first conducting films 91 are formed of a conducting material such as doped polysilicon or doped amorphous silicon containing boron. The first stack structure ST1 becomes the gate electrodes of the back gate portion BG later.

Trenches TR1 are then formed in formation areas of the BG link portions 50 using a lithographic technique and an etching technique as shown in FIG. 4B. Etching of the trenches TR1 is stopped when the trenches TR1 reach the sacrifice layer 95.

A material of the BG link portions 50 is deposited in the trenches TR1 and the material of the BG link portions 50 is polished by the CMP method or the like until a surface of the first stack structure ST1 is exposed. The BG link portions 50 passing through the first stack structure ST1 and electrically connecting the first conducting films 91 are thereby formed as shown in FIG. 4C. The material of the BG link portions 50 can be, for example, polysilicon or tungsten containing carbon as mentioned above. FIG. 8B is a view showing a layout of the sacrifice layer 95 and the BG link portions 50.

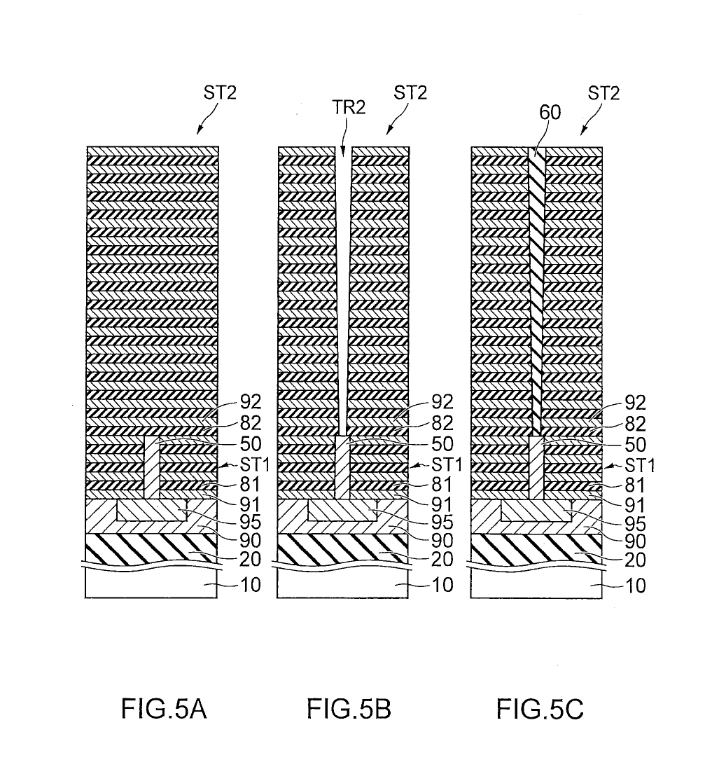

Desired numbers of the second insulating films 82 and the second conducting films 92 are then stacked on the first stack structure ST1 and the BG link portions 50 as shown in FIG. 5A. The second stack structure ST2 is thereby formed. As mentioned above, because the second conducting films 92 are provided to supply oxygen during formation of the memory holes MH, the second conducting films 92 can be thinner than the first conducting films 91. The second insulating films 82 are formed of an oxide film such as a silicon dioxide film and the second conducting films 92 are formed of a conducting material such as doped polysilicon or doped amorphous silicon containing boron. The second stack structure ST2 becomes the control electrodes of the memory cells MC later.

Trenches (slits) TR2 passing through the second stack structure ST2 and reaching the BG link portions 50 are then formed using a lithographic technique and an etching technique as shown in FIG. 5B. At that time, the BG link portions 50 can function as etching stoppers because the BG link portions 50 are formed of polysilicon or tungsten containing carbon. The second conducting films 92 can be silicided via the trenches TR2.

A material of the insulating films 60 is deposited in the trenches TR2 and is polished by the CMP method or the like until a surface of the second stack structure is exposed as shown in FIG. 5C. Accordingly, the insulating films 60 are formed. The insulating films 60 can be an insulating film such as a silicon dioxide film or a silicon nitride film.

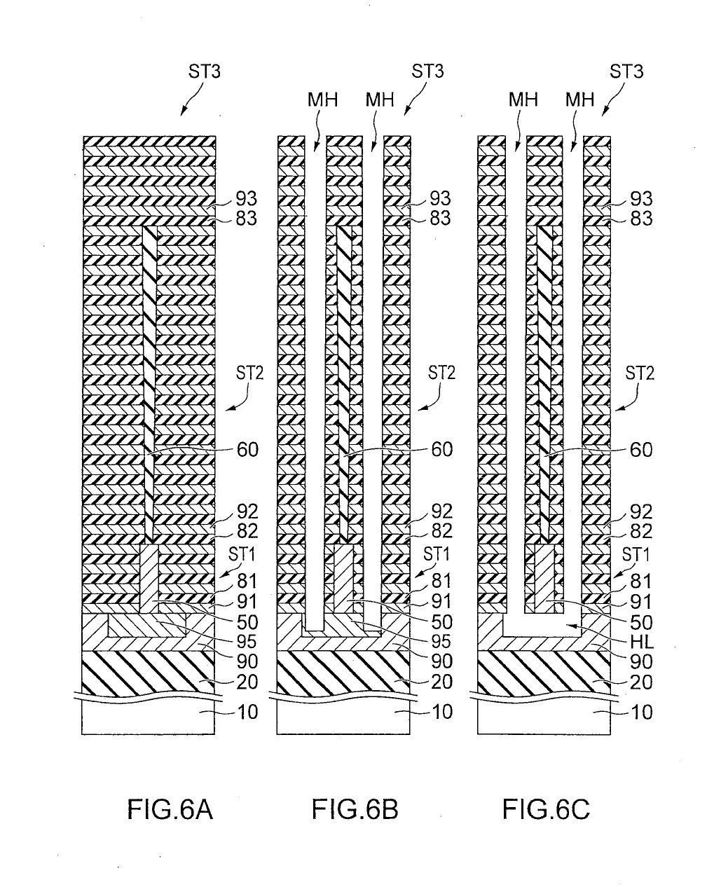

Desired numbers of the third insulating films 83 and the third conducting films 93 are stacked on the second stack structure ST2 and the insulating films 60 as shown in FIG. 6A. The third stack structure ST3 is thereby formed. The third insulating films 83 are formed of an oxide film such as a silicon dioxide film and the third conducting films 93 are formed of a conducting material such as doped amorphous silicon or doped polysilicon containing boron. The third stack structure ST3 becomes the gate electrodes of the select gate portion SG later.

Memory holes (trenches) MH passing through the third stack structure ST3 and the second stack structure ST2 and reaching the first stack structure ST1 are then formed using a lithographic technique and an etching technique as shown in FIG. 6B. Anisotropic etching such as an RIE (Reactive Ion Etching) method can be used as the etching technique. The memory holes MH are formed to reach the sacrifice layer 95 provided under the first stack structure ST1.

At that time, the bottom portions of the memory holes MH (the gate electrode portions of the back gate portion BG) have the stack structure including the insulating films 81 and the conducting films 91 (the first stack structure ST1) as mentioned above. Accordingly, during formation of the memory holes MH, the insulating films 81 and the conducting films 91 are alternately etched. Therefore, while CF-based depositions are produced during etching of the conducting films 91 (polysilicon, for example), oxygen is supplied during etching of the insulating films 81 (a silicon dioxide film, for example). The depositions produced during etching of the conducting films 91 are thus oxidized during etching of the insulating films 81 and are reduced or disappear.

When the depositions at the bottom portions of the memory holes MH are reduced or disappear, etching of the widths (diameters) at the bottom portions of the memory holes MH progresses and the memory holes MH close to a design value are obtained. Because this eliminates the need of excess overetching, the memory holes MH can be maintained in satisfactory shapes and also adverse influences on the peripheral circuit can be suppressed.

The sacrifice layer 95 is then removed by isotropic etching such as wet etching or a CDE (Chemical Dry Etching) method as shown in FIG. 6C. A hollow HL is thereby formed at the bottom portions of the memory holes MH. FIG. 8C is a view showing a layout of the hollow HL, the memory holes MH, and the insulating films 60.

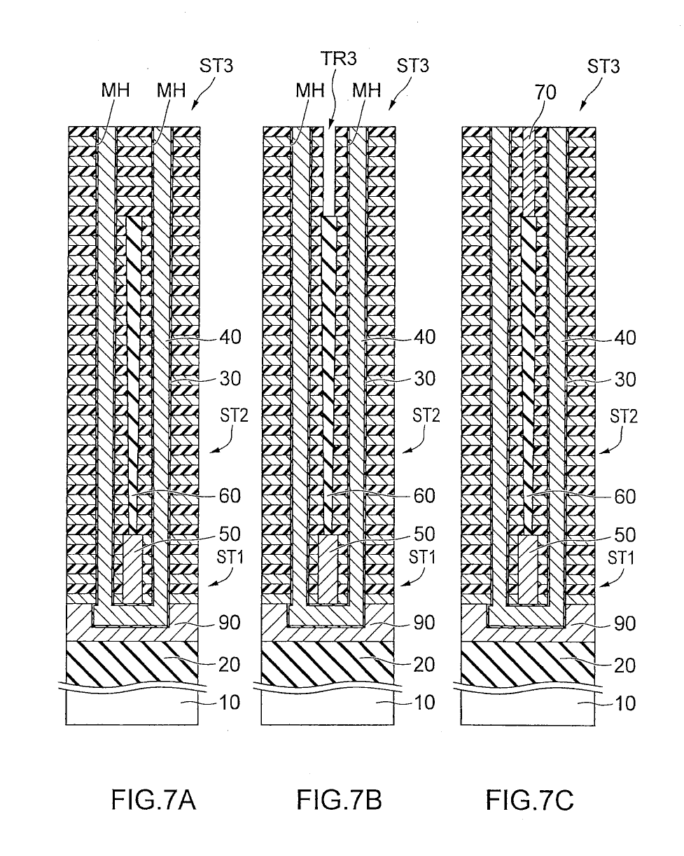

The charge accumulation layer 30 is then formed on the inner surfaces of the memory holes MH as shown in FIG. 7A. The charge accumulation layer 30 is formed of a stack insulating film such as an ONO film or a NONON film. The charge accumulation layer 30 is formed also on the inner surfaces of the hollow HL. When the charge accumulation layer 30 is an ONO film and the second conducting films 92 are a silicide, a NOMOS structure is formed.

A material of the silicon pillars 40 is then deposited in the memory holes MH and the hollow HL. The silicon-pillar coupling portion CNT and the silicon pillars 40 are thereby formed as shown in FIG. 7A. The material of the silicon pillars 40 can be a conducting material such as doped polysilicon or doped amorphous silicon. The silicon-pillar coupling portion CNT is formed under the BG link portions 50 and electrically connects adjacent two of the silicon pillars 40. The silicon pillars 40 and the silicon-pillar coupling portion CNT are insulated from the first to third stack structures ST1 to ST3 by the charge accumulation layer 30.

Trenches TR3 passing through the third stack structure ST3 and reaching the insulating films 60 are then formed using a lithographic technique and an etching technique as shown in FIG. 7B. The trenches TR3 are formed in the stack direction of the third insulating films 83 and the third conducting films 93.

A material of the SG link portions 70 is then deposited in the trenches TR3 and polished by the CMP method or the like until a surface of the third stack structure ST3 is exposed as shown in FIG. 7C. The SG link portions 70 are thereby formed. The SG link portions 70 are formed of a conducting material such as doped polysilicon, doped amorphous silicon, or tungsten containing carbon and electrically connect the third conducting films 93 in the third stack structure ST3. Accordingly, the third stack structure ST3 can function as the gate electrodes of the select gate portion SG.

Thereafter, interlayer dielectric films, contact plugs, wires, and the like (not shown) are formed, thereby completing the memory 100.

According to the present embodiment, the gate electrodes of the back gate portion BG have the stack structure including the insulating films 81 and the conducting films 91 (the first stack structure ST1). With this configuration, during formation of the memory holes MH, the insulating films 81 and the conducting films 91 are alternately etched. Therefore, depositions (carbon-containing depositions) produced during etching of the conducting films 91 are oxidized during etching of the insulating films 81 and are reduced or disappear. As a result, the memory holes MH can be formed in desired shapes while excess overetching is suppressed. Therefore, the memory holes MH can be maintained in satisfactory shapes and also adverse influences on the peripheral circuit can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first stack structure comprising at least one first insulating film and a plurality of first conducting films and provided above a surface of a substrate;
a link portion electrically connecting the first conducting films and provided in the first stack structure;
a second stack structure comprising a plurality of second insulating films and a plurality of second conducting films and provided on the first stack structure; and
a semiconductor pillar passing through the second stack structure to reach the first stack structure and being insulated from the first and second stack structures.

2. The device of claim 1, wherein the first and second conducting films function as gate electrodes for flowing current in the semiconductor pillar.

3. The device of claim 1, wherein
the second conducting films are gate electrodes of a plurality of memory cells, respectively,
the first conducting films form gate electrodes of a first select portion selecting the memory cells,
the device further comprises a second select portion selecting the memory cells on the second stack structure, and
the memory cells can be selected by the first and second select portions.

4. The device of claim 2, wherein
the second conducting films are gate electrodes of a plurality of memory cells, respectively,
the first conducting films form gate electrodes of a first select portion selecting the memory cells,
the device further comprises a second select portion selecting the memory cells on the second stack structure, and
the memory cells can be selected by the first and second select portions.

5. The device of claim 1, wherein the first insulating films are thinner than the second insulating films.

6. The device of claim 2, wherein the first insulating films are thinner than the second insulating films.

7. The device of claim 3, wherein the first insulating films are thinner than the second insulating films.

8. The device of claim 1, wherein the link portion is formed of polysilicon or tungsten containing carbon.

9. The device of claim 2, wherein the link portion is formed of polysilicon or tungsten containing carbon.

10. The device of claim 3, wherein the link portion is formed of polysilicon or tungsten containing carbon.

11. The device of claim 1, wherein
a material of the first conducting films is polysilicon or amorphous silicon, and
a material of the second conducting films is a silicide.

12. The device of claim 2, wherein
a material of the first conducting films is polysilicon or amorphous silicon, and
a material of the second conducting films is a silicide.

13. The device of claim 3, wherein
a material of the first conducting films is polysilicon or amorphous silicon, and
a material of the second conducting films is a silicide.

14. The device of claim 1, wherein
a plurality of the semiconductor pillars are provided, and
the link portion is located between adjacent ones of the semiconductor pillars and is insulated from the semiconductor pillars.

15. The device of claim 1, further comprising a semiconductor-pillar coupling portion electrically connecting adjacent ones of the semiconductor pillars to each other under the link portion.

16. A manufacturing method of a semiconductor device, the method comprising:
forming a first stack structure above a surface of a substrate, the first stack structure comprising at least one first insulating film and a plurality of first conducting films;
forming a link portion passing through the first stack structure and electrically connecting the first conducting films;
forming a second stack structure on the first stack structure, the second stack structure comprising a plurality of second insulating films and a plurality of second conducting films;
forming a trench passing through the second stack structure and reaching the first stack structure; and
forming a semiconductor pillar in the trench, the semiconductor pillar being insulated from the first and second stack structures.

17. The method of claim 16, wherein the first insulating films are thinner than the second insulating films.

18. The method of claim 16, wherein
the trench is formed to reach a sacrifice layer under the first stack structure,
the method further comprises:
removing the sacrifice layer via the trench to form a hollow; and
depositing a conducting material in the hollow via the trench to form a semiconductor-pillar coupling portion under the link portion, the semiconductor-pillar coupling portion connecting a plurality of the semiconductor pillars adjacent to each other.

19. The method of claim 16, wherein the link portion is formed of polysilicon or tungsten containing carbon.

20. The method of claim 16, wherein
a material of the first conducting films is polysilicon or amorphous silicon, and
a material of the second conducting films is a silicide.
